(19) United States
(12) Patent Application Publication
(10) Pub. No.: US 2005/0161791 A1
(43) Pub. Date: Jul. 28, 2005

(54) Multiple die-spacer for an integrated circuit

(75) Inventor: Edgardo R. Hortaleza, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/763,349

(22) Filed: Jan. 23, 2004

(51) Int. Cl. H01L 23/02

(52) U.S. Cl. 257/685; 257/782; 438/109

(57) ABSTRACT

A method of forming an integrated circuit includes placing a first die and adhering multiple spacers to the first die. The method further includes adhering a second die to the spacers. The second die is adhered such that the spacers are between the first and second dies.

### TECHNICAL FIELD OF THE INVENTION

The present invention relates generally to the field of integrated circuits and, more particularly, to a multiple die-spacer for an integrated circuit.

### BACKGROUND OF THE INVENTION

Integrated circuits may include several physically separate units, known as dies, that perform electrical functions. Dies may be in a stacked configuration within the integrated circuit, in which case the dies are separated by spacers that hold the dies apart. Spacers may be formed using a variety of materials, such as adhesives and silicon. During the process of forming the integrated circuit, spacers and dies may be subject to conditions such as heat and pressure. In some cases, this may result in damage to the integrated circuit.

### SUMMARY OF THE INVENTION

In accordance with one embodiment of the present invention, an integrated circuit includes a first die and a second die. Between the first and second dies are a plurality of spacers. Each spacer is attached to the first die and the second die.

In accordance with another embodiment of the present invention, a method of forming an integrated circuit includes placing a first die and adhering multiple spacers to the first die. The method further includes adhering a second die to the spacers. The second die is adhered such that the spacers are between the first and second dies.

Important technical advantages of certain embodiments of the present invention include avoiding damage to an integrated circuit produce by conditions such as heat and pressure. By reducing the total length of spacer material in contact with dies, such embodiments reduce the amount of stress on dies due to spacers and dies having different thermal expansion coefficients. As a result, the possibility of damage is reduced.

Other important technical advantages of certain embodiments of the present invention include use of less spacer material. This reduction may help to conserve materials, thus potentially lowering cost. Furthermore, it may allow greater flexibility in design by freeing up space that would otherwise be used by spacer material.

Still other advantages may include selective placement of spacers on a die. Putting spacers at particular locations on the die may help to make particular areas of die more accessible. It may also help to position stresses caused by spacers in places on the die that are less vulnerable to damage, and to reduce those stresses in some cases.

Additional technical advantages of the present invention will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present invention and its advantages, reference is now made to the following description, taken in conjunction with the accompanying drawings, in which:

FIG. 1 illustrates a side view of an integrated circuit using a conventional spacer;

FIG. 2 illustrates a conventional spacer;

FIG. 3 illustrates an integrated circuit using multiple die spacers;

FIG. 4 illustrates multiple die spacers; and

FIG. 5 is a flow chart illustrating a method for forming an integrated circuit using multiple die spacers.

### DETAILED DESCRIPTION OF EXAMPLE EMBODIMENTS OF THE INVENTION

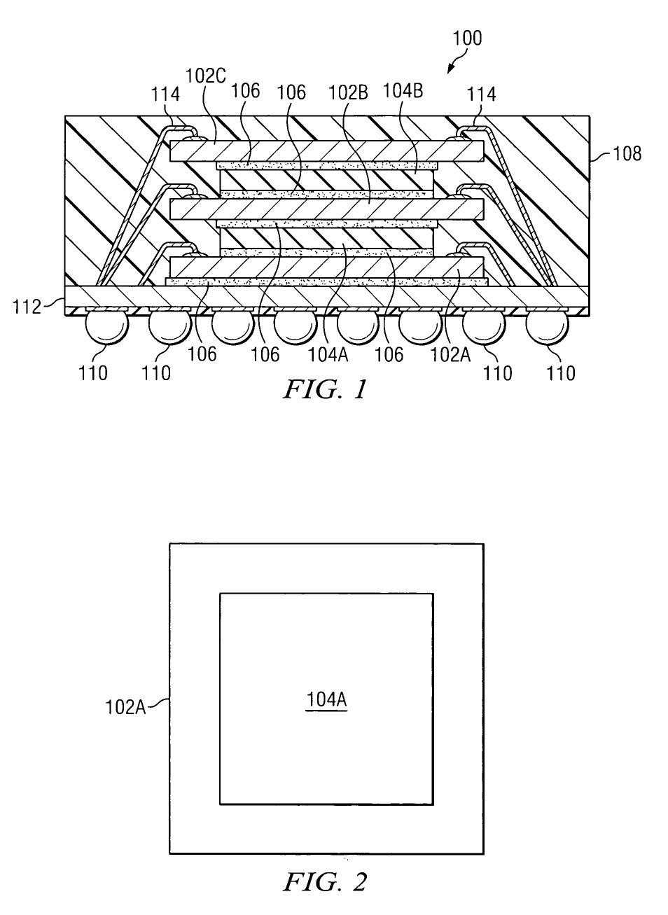

FIG. 1 illustrates an integrated circuit 100 that includes a bottom die 102A, a middle die 102B, and a top die 102C, collectively referred to as “dies 102.” Dies 102 are separated by conventional spacers 104A and 104B (collectively referred to as “spacers 104”). The position of spacer 102A relative to die 102A from a top perspective is shown in FIG. 2. Adhesive 106 is used to adhere components of integrated circuit to one another. Components of integrated circuit are surrounded by an encapsulating material 108, such as a mold resin, that integrates components into a single package. In the depicted embodiment, encapsulating material 108 includes balls 110 that serve as a base for integrated circuit 100.

Dies 102 are components of integrated circuit 100 that perform selected electrical functions. Dies 102 may include silicon, metal, or other conducting or semiconducting material capable of performing one or more desired electrical operations. In a stacked die configuration, dies 102 may be manufactured separately and assembled into a single package. In the depicted embodiment, dies 102 are electrically coupled to a conductive plating 112 by wires 114. Conductive plating 112 and wires 114 delivery electricity for powering dies 102 for their respective operations.

Spacers 104 represent materials that hold dies 102 apart from one another. The amount of spacing required between dies 102 may be determined by the space needed to prevent interference between dies 102, the room needed to insert components such as wires 114, or other design considerations. Spacers 104 may be formed using any suitable materials, including silicon, resins, or other reasonably rigid material mechanically able to maintain separation between dies 102 under reasonable operating conditions, and may conceivably be integral to dies 102. In the depicted embodiment, spacers 104 are adhered to dies 102 using adhesive 106. Adhesive 106 may be any suitable adhesive material, including resin, glue, or other material capable of adhering to dies 102. In locations where it may be desirable to electrically insulate components from one another, adhesive 106 may be nonconductive, but generally, either conductive or nonconductive adhesives may be used.

To form integrated circuit 100, spacers 104 are stacked on dies 102 using adhesive 106. Bottom die 102A is adhered to conductive plating 112. Adhesive 106 is placed on bottom die 102A, and spacer 104A is then placed on top of adhesive 106. Adhesive 106 is then placed on top of spacer 104A, allowing dies 102B and 102C and spacer 104B to be stacked in like manner. When the stacking process is complete, wires 114 may be attached and the entire package encapsulated with encapsulating material 108, thus forming integrated circuit 100.

During formation, components of integrated circuit 110 may be subject to conditions such as heat and pressure. Because dies 102 and spacers 104 may be formed from different materials, they may have different properties, which may cause them to respond to such conditions differently. For example, the materials may have different thermal expansion coefficients, which may cause one to expand more quickly than the other. But since dies 102 and spacers 104 are adhered to one another, this may create mechanical stresses on dies 102. In many cases, such problems may not be detected until the finished product is examined by grinding away a portion of encapsulation material 108, such as balls 110.

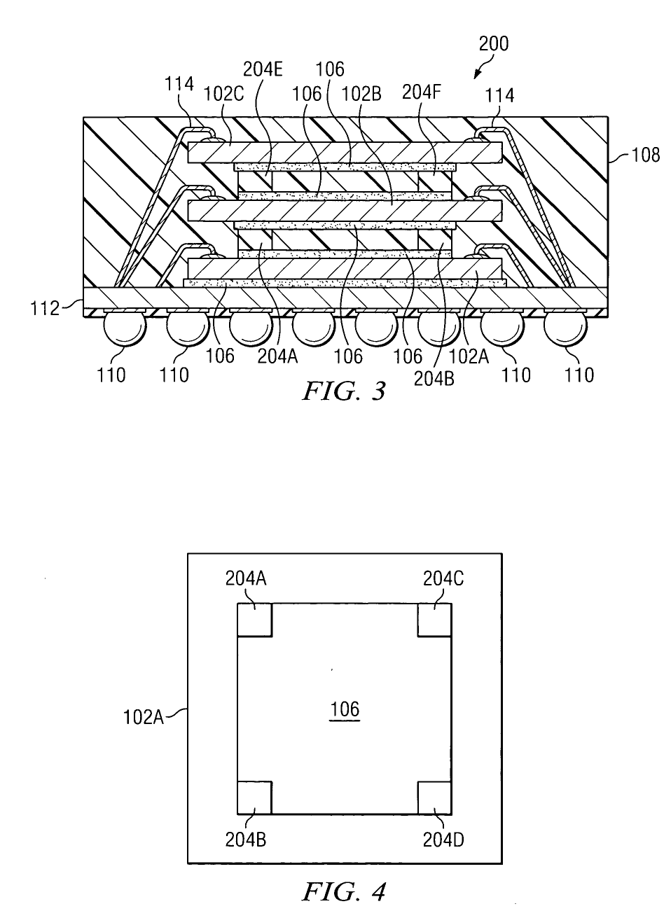

FIG. 3 illustrates an integrated circuit 200 that reduces the risks associated with making dies 102 and spacers 104 from different materials. In integrated circuit 200, spacers 104 are replaced with multiple spacers 204 (referring to spacers 204A, 204B, 204C, 204D, 204E, and 204F) of like materials to those of spacers 104. Spacers 204 arranged in spacer layers. In the embodiment depicted in the top view of die 102A, illustrated in FIG. 4, spacers 204A, 204B, 204C, and 204D form a square arrangement corresponding to the square shape of die 102A. The depicted square arrangement is only one of many possible arrangements of spacers 204, and any suitable geometric arrangement that provides a desired level of mechanical stability may also be used. In particular, it may be advantageous to adapt the shape of the arrangement to the shape of die 102

Although it is somewhat more complicated to assemble integrated circuit 200 using multiple spacers 204, the arrangement may provide several technical advantages. For example, the total amount of edge length of spacers 204 adhered to dies 102 may be reduced. Thus, in cases where the different behavior of materials under conditions varies in proportion to length, such as thermal expansion, the reduced length reduces the mechanical stress exerted because of the different expansion coefficients of die 102 and spacer 104. Another advantage may be the ability to place spacers 204 in particular locations on die 102 to increase accessibility of particular regions of die 102 or to reduce mechanical stress on particular areas. Other technical advantages may include conservation of materials used in spacers 104 and increased room within integrated circuit 200 for insertion of components such as wires 114.

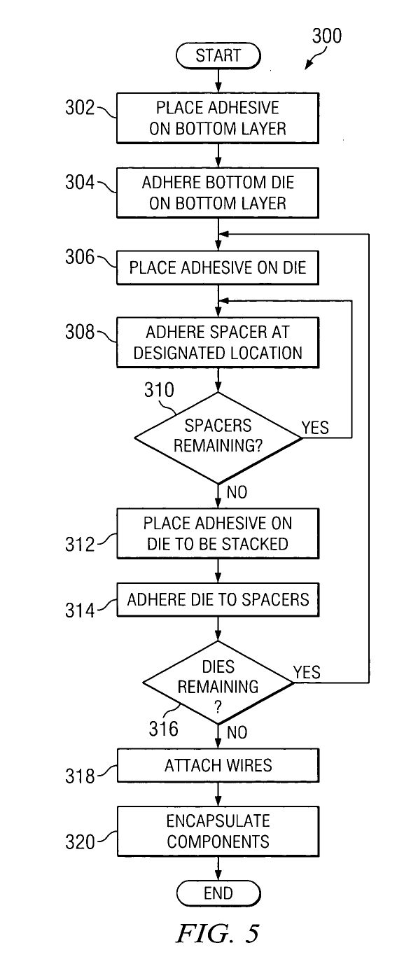

FIG. 5 is a flowchart 300 that shows one example of a method for forming an stacked-die integrated circuit 200 using multiple spacers 204. Adhesive 106 is placed on the bottom layer, which may be conductive plating 112, at step 302. Bottom die 102A is placed on top of adhesive 106 at step 304. Adhesive 106 is placed on die 102A at step 306. Adhesive 106 may be applied selectively at the location of spacers 204 or, alternatively, may be deposited in a layer that includes the location of spacers 204 or may be placed on spacers 204 themselves.

A spacer 204 is placed at its designated location in the spacer layer atop die 102 at step 308. Additional spacers 204 are placed in the spacer layer until all spacers 204 are placed, as shown by decision step 316. Adhesive 106 is placed on the next die 102 to be stacked at step 312. Alternatively, adhesive 106 may be placed on spacers 204. Die 102 is then stacked and adhered on spacers 204 at step 314.

At decision step 316, if there are additional dies to be stacked, then the described method of stacking spacers 204 on a placed die 102 and stacking a new die 102 on top of spacers 204 may be repeated from step 306. Otherwise, wires 114 may be attached to dies 102 at step 318, and the components may be encapsulated at step 320. The method described above is only one example of a method for forming integrate circuit 200, and it should be understood that other methods of formation consistent with the description above are also possible.

Although the present invention has been described with several embodiments, a myriad of changes, variations, alterations, transformations, and modifications may be suggested to one skilled in the art. For example, the reference to particular directions, such as “top” or “upper,” does not limit the possibility of other directional arrangements. It is intended that the present invention encompass such changes, variations, alterations, transformations, and modifications as fall within the scope of the appended claims.

1. An integrated circuit, comprising:
a substrate with a conductive layer;
a first die adhered to the substrate;
a first adhesive layer on a top surface of the first die;
a plurality of spacers adhered to the first adhesive layer, the plurality of spacers arranged in a rectangular pattern on top of the first die;
a second die having a second adhesive layer on a bottom surface of the second die, wherein the second adhesive layer is adhered to the plurality of spacers such that the plurality of spacers are between the first and second dies;
a plurality of wires coupled to the conductive layer and to the first and second dies operable to conduct electricity between the conductive layer and the first and second dies; and
an encapsulating material operable to form the first and second dies, the spacers, the substrate, and the wires into a single package.

2. An integrated circuit, comprising:
a first die;
a second die;
a plurality of spacers between the first die and the second die, wherein each of the spacers is adhered to the first die and the second die.

3. (canceled)

4. The integrated circuit of claim 2, wherein the spacers are formed from silicon.

5. The integrated circuit of claim 2, wherein the spacers are formed from an adhesive material.

6. The integrated circuit of claim 2, wherein:
there are exactly four spacers in the plurality of spacers; and
the spacers are arranged in a rectangular pattern.

7. The integrated circuit of claim 2, wherein:
the dies are formed from a first material; and
the spacers are formed from a second material different from the first material.

8-14. (canceled)

15. An integrated circuit made by a process, the process comprising:
placing a first die;
adhering a plurality of spacers to the first die;
adhering a second die to the plurality of spacers such that the spacers are between the first and second dies.

16. The integrated circuit of claim 15, wherein:
the plurality of spacers are a first plurality of spacers, and the first plurality of spacers is adhered to a first side of the second die; and
the process further comprises:
adhering a second plurality of spacers on a second side of the second die; and
adhering a third die to the second plurality of spacers such that the second plurality of spacers is in between the second and third dies.

17. The integrated circuit of claim 15, wherein the process further comprises enclosing the first and second dies and the spacers in an encapsulating material.

18. The integrated circuit of claim 15, wherein:
the step of placing the first die comprises adhering the first die to a substrate with a conductive layer; and
the process further comprises:
coupling a plurality of wires to the conductive layer; and
coupling each of the wires to at least one of the dies.

19. The integrated circuit of claim 15, wherein:
there are exactly four spacers in the plurality of spacers; and
the step of adhering the spacers comprises arranging the spacers in a rectangular arrangement.

20. The integrated circuit of claim 15, wherein:
the dies are formed from a first material; and
the spacers are formed from a second material different from the first material.
